(19) United States
(12) Patent Application Publication
(10) Pub. No.: US 2009/0032828 A1
(43) Pub. Date: Feb. 5, 2009

(54) III-Nitride Device Grown on Edge-Dislocation Template

(75) Inventors: Linda T. Romano, Sunnyvale, CA (US); Patrick N. Grillot, San Jose, CA (US)

Correspondence Address: PATENT LAW GROUP LLP, 2635 NORTH FIRST STREET, SUITE 223, SAN JOSE, CA, 95134, US

(73) Assignee: PHILIPS LUMILEDS LIGHTING COMPANY, LLC, San Jose, CA (US)

(21) Appl. No.: 11/833,921

(22) Filed: Aug. 3, 2007

(51) Int. Cl. H01L 33/00; H01L 21/20

(52) U.S. Cl. 257/94; 438/47; 438/478; 257/E21.09; 257/E33.001

(57) ABSTRACT

A semiconductor light emitting device includes a wurtzite III-nitride semiconductor structure including a light emitting layer disposed between an n-type region and a p-type region. A template layer and a dislocation bending layer are grown before the light emitting layer. The template layer is grown such that at least 70% of the dislocations in the template layer are edge dislocations. At least some of the edge dislocations in the template layer continue into the dislocation bending layer. The dislocation bending layer is grown to have a different magnitude of strain than the template layer. The change in strain at the interface between the template layer and the dislocation bending layer causes at least some of the edge dislocations in the template layer to bend to a different orientation in the dislocation bending layer. Semiconductor material grown above the bent edge dislocations may exhibit reduced strain.

### BACKGROUND

1. Field of Invention

The present invention relates to growth techniques and device structures for semiconductor light emitting devices.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the UV, visible, and possibly the infrared spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions. These III-nitride materials are also of interest for other optoelectronic and also electronic devices, such as field effect transistors (FETs), and detectors.

### SUMMARY

In accordance with embodiments of the invention, a semiconductor light emitting device includes a wurtzite III-nitride semiconductor structure including a light emitting layer disposed between an n-type region and a p-type region. A template layer and a dislocation bending layer are grown before the light emitting layer. The template layer is grown such that at least 70% of the dislocations in the template layer are edge dislocations. At least some of the edge dislocations in the template layer continue into the dislocation bending layer. The dislocation bending layer is grown to have a different magnitude of strain than the template layer. The change in strain at the interface between the template layer and the dislocation bending layer causes at least some of the edge dislocations in the template layer to bend to a different orientation in the dislocation bending layer. Semiconductor material grown above the bent edge dislocations may exhibit reduced strain.

### BRIEF DESCRIPTION OF THE DRAWINGS

FIG. 1 is a cross sectional view of a semiconductor structure including an edge-dislocation template, according to embodiments of the invention.

FIG. 2 illustrates several major crystallographic planes of a wurtzite structure such as sapphire.

FIG. 3 illustrates a portion of a flip chip light emitting device from which the growth substrate has been removed.

FIG. 4 illustrates screw, edge, and mixed dislocations in a wurtzite crystal.

FIG. 5 is an exploded view of a packaged light emitting device.

### DETAILED DESCRIPTION

The performance of a semiconductor light emitting device may be gauged by measuring the external quantum efficiency, which measures the number of photons extracted from the device per electron supplied to the device. As the current density applied to a conventional III-nitride light emitting device increases, the external quantum efficiency of the device initially increases, then decreases. As the current density increases past zero, the external quantum efficiency increases, reaching a peak at a given current density (for example, at about 10 A/cm² for some devices). As current density increases beyond the peak, the external quantum efficiency initially drops quickly, then the decrease slows at higher current density (for example, beyond 200 A/cm² for some devices). The quantum efficiency of a device also decreases as the InN composition in the light emitting region increases and as the wavelength of emitted light increases.

Since native III-nitride growth substrates are generally expensive, not widely available, and impractical for growth of commercial devices, III-nitride devices are often grown on sapphire (Al₂O₃) or SiC substrates. Such non-native substrates have different lattice constants than the III-nitride device layers grown on the substrate, different thermal expansion coefficients, and different chemical and structural properties than the device layers, resulting in strain in the III-nitride device layers. Strain in the device layers, in particular in the light emitting layer, may be one cause of the decrease in quantum efficiency as the current density increases.

As used herein, an “in-plane” lattice constant refers to the actual lattice constant of a layer within the device, and a “relaxed” or “bulk” lattice constant refers to the lattice constant of relaxed, free-standing material of a given composition. The amount of strain in a layer is defined in Eq. (1).

strain=ε=(aᵢₙ₋ₚₗₐₙₑ−a_{relaxed})/a_{relaxed} (1)

Note that strain, ε, in Eq. (1) can be either positive or negative, i.e., ε>0 or ε<0. In an unstrained film, aᵢₙ₋ₚₗₐₙₑ=a_{relaxed}, so ε=0 in Eq. (1). A film where ε>0 is said to be under tensile strain, or under tension, while a film where ε<0 is said to be under compressive strain, or under compression. Examples of tensile strain include a strained AlGaN film grown over unstrained GaN, or a strained GaN film grown over unstrained InGaN. In both cases, the strained film has a relaxed lattice constant that is smaller than the relaxed lattice constant of the unstrained layer on which it is grown, so the in-plane lattice constant of the strained film is stretched to match that of the unstrained layer, giving ε>0 in Eq. (1), according to which the film is said to be under tension. Examples of compressive strain include a strained InGaN film grown over unstrained GaN, or a strained GaN film grown over unstrained AlGaN. In both cases, the strained film has a relaxed lattice constant that is larger than the relaxed lattice constant of the unstrained layer on which it is grown, so the in-plane lattice constant of the strained film is compressed to match that of the unstrained layer, giving ε<0 in Eq. (1), according to which the film is said to be under compression.

In a tensile film, the strain acts to pull the atoms apart from one another in order to increase the in-plane lattice constant. This tensile strain is often undesirable, because the film can respond to the tensile strain by cracking, which decreases the strain in the film, but compromises the structural and electrical integrity of the film. In a compressive film, the strain acts to push the atoms together, and this effect can reduce the incorporation of large atoms such as indium in an InGaN film, for example, or can degrade the material quality of the InGaN active layer in an InGaN LED. In many cases, tensile and compressive strain are both undesirable, and it is beneficial to decrease the tensile or compressive strain in the various layers of the device. In such cases, it is more convenient to refer to the absolute value, or magnitude of the strain, as defined in Eq. (2). As used herein, the term “strain” shall be understood to mean the absolute value, or magnitude of the strain, as defined in Eq. (2).

strain=|ε|=|(aᵢₙ₋ₚₗₐₙₑ−a_{relaxed})|/a_{relaxed} (2)

When a III-nitride device is conventionally grown on Al₂O₃, the first structure grown on the substrate is generally a GaN template layer with an in-plane a-lattice constant of about 3.189 Å or less. The GaN template serves as a lattice constant template for the light emitting region in that it sets the lattice constant for all of the device layers grown above the template layer, including the InGaN light emitting layer. Since the relaxed lattice constant of InGaN is larger than the in-plane lattice constant of the conventional GaN template, the light emitting layer is compressively strained when grown over a conventional GaN template. For example, a light emitting layer configured to emit light of about 450 nm may have a composition In_{0.16}Ga_{0.84}N, a composition with a relaxed lattice constant of 3.242 Å, as compared to the lattice constant of GaN, up to 3.189 Å. The difference in the relaxed lattice constant of the light emitting layer and the in-plane lattice constant of the GaN template results in strain in the light emitting layer of at least 1.6%. As the InN composition in the light emitting layer increases, as in devices designed to emit light at longer wavelengths, the compressive strain in the light emitting layer also increases.

Due to the different chemical and structure properties of the substrate and the III-nitride layer, growth of III-nitride layers on non-native substrates also typically results in defects in the III-nitride layers, such as crystal dislocations. Dislocations are defined by a dislocation line and a Burgers vector. A dislocation line forms the boundary between a slipped part of the crystal and an unslipped part of the crystal. At the boundary, the slipped portion is shifted from perfect crystal alignment with the unslipped portion. The magnitude and direction of shift define the Burgers vector.

Dislocations can be classified as screw dislocations, edge dislocations, and mixed dislocations. FIG. 4 illustrates the different types of dislocations in a wurtzite crystal. Two dislocation lines, 50A and 50B, are illustrated in FIG. 4. In a screw dislocation, the Burgers vector (52A and 52B, respectively) is parallel to the dislocation line (50A and 50B). In an edge dislocation, the Burgers vector 54A is perpendicular to the dislocation line 50A. In a mixed dislocation, the relationship between the Burgers vector (56A and 56B, respectively) and the dislocation line (50A and 50B) is between parallel and perpendicular.

In a conventional III-nitride device with the device layers grown over a GaN template, in general about 50% of the dislocations are edge dislocations, and 50% of the dislocations are mixed or screw dislocations. At the interface between layers of different compositions, the change in strain may cause bending of the edge dislocations. Mixed and screw dislocations generally do not bend when exposed to a change in strain.

In accordance with embodiments of the invention, the device layers in a III-nitride device are grown over a template with more edge dislocations than screw or mixed dislocations. The template includes one or more layers grown to encourage edge dislocations to bend, which may reduce the strain above the bend in the dislocation.

The device layers grown over the template include at least one light emitting layer sandwiched between at least one n-type layer and at least one p-type layer. Additional layers of different compositions and dopant concentration may be included in each of the n-type region, light emitting region, and p-type region. For example, the n- and p-type regions may include layers of opposite conductivity type or layers that are not intentionally doped, release layers designed to facilitate later release of the growth substrate or thinning of the semiconductor structure after substrate removal, and layers designed for particular optical or electrical properties desirable for the light emitting region to efficiently emit light. In some embodiments, the n-type layer sandwiching the light emitting layer may be part of the template.

In the embodiments described below, the InN composition in the light emitting layer or layers may be low, such that the device emits blue or UV light, or high, such that the device emits green or longer wavelength light. In some embodiments, the device includes one or more quantum well light emitting layers. Multiple quantum wells may be separated by barrier layers. For example, each quantum well may have a thickness greater than 15 Å.

In some embodiments, the light emitting region of the device is a single, thick light emitting layer with a thickness between 50 and 600 Å, more preferably between 100 and 250 Å. The optimal thickness may depend on the number of defects within the light emitting layer. The concentration of defects in the light emitting region is preferably limited to less than 10⁹ cm⁻², more preferably limited to less than 10⁸ cm⁻², more preferably limited to less than 10⁷ cm⁻², and more preferably limited to less than 10⁶ cm⁻².

In some embodiments, at least one light emitting layer in the device is doped with a dopant such as Si to a dopant concentration between 1×10¹⁸ cm⁻³ and 1×10²⁰ cm⁻³. Si doping may influence the in-plane a-lattice constant in the light emitting layer, potentially further reducing the strain in the light emitting layer.

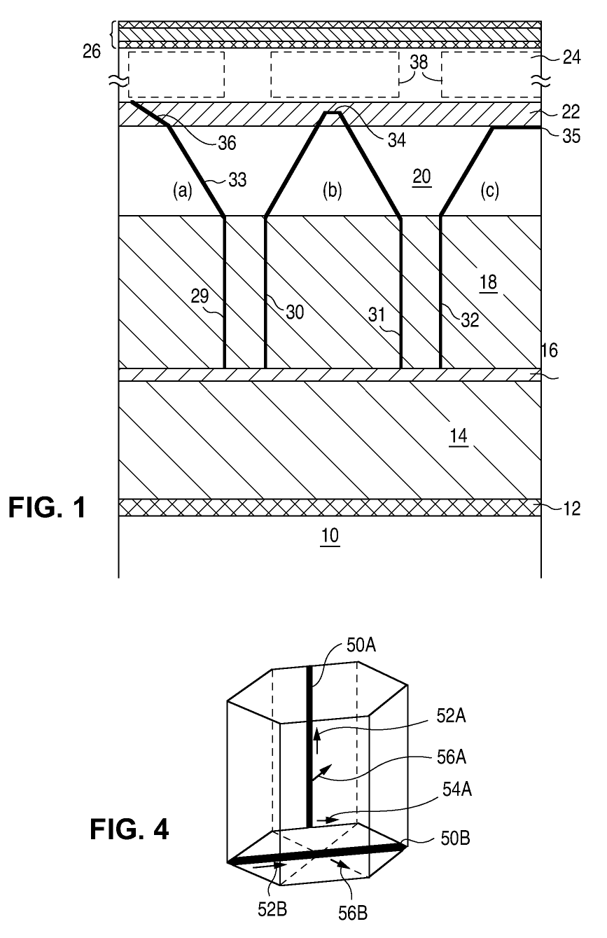

FIG. 1 illustrates III-nitride layers grown on a sapphire substrate, according to embodiments of the invention. A nucleation layer 12, typically GaN, is grown first over a sapphire substrate 10. Nucleation layer 12 is typically a low quality, non-single crystal layer such as an amorphous, polycrystalline, or cubic phase GaN layer grown to a thickness of, for example, up to 500 angstroms, at a temperature between 400 and 750° C. A high temperature layer 14 is grown over nucleation layer 12. High temperature layer 14 may be, for example, a high quality, crystalline GaN, InGaN, AlGaN, or AlInGaN layer grown to a thickness of at least 500 angstroms, at a temperature between 900 and 1150° C. In some embodiments, nucleation layer 12 and high temperature layer 14 may be omitted, and nucleation layer 16, described below, is grown directly on growth substrate 10.

A second nucleation layer 16, also typically a low quality, non-single crystal layer such as an amorphous, polycrystalline, or cubic phase layer, is grown over high temperature layer 14. Second nucleation layer 16 is grown under nucleation conditions that favor the formation of edge dislocations over other types of dislocations. For example, nucleation layer 16 may be GaN or InGaN, grown at a low temperature, for example less than 650° C. Nucleation layer 16 may be grown at the same growth temperature as nucleation layer 12, though it need not be. Nucleation layer 16 is generally thinner than nucleation layer 12, and may be grown at the same or a slower growth rate. For example, nucleation layer 12 may be a 200-500 angstrom thick GaN layer and nucleation layer 16 may be a 100-200 angstrom thick GaN or InGaN layer, for example with an InN composition less than 5%. In some embodiments, nucleation layers 12 and 16 are grown at a growth rate between 0.1 and 10 Å/s, more preferably less than 5 Å/s, more preferably between 0.5 and 2 Å/s, to avoid an undesirably rough surface. Nucleation layers 12 and 16 are also typically grown under a relatively low flow of group V precursor, often NH₃. For example, NH₃ is often less than 50% of the total input flow, more preferably less than 30% of the input flow, and more preferably less than 20% of the total input flow.

A high temperature layer 18, often InGaN or GaN, is grown over nucleation layer 16. In some embodiments, high temperature layer 18 is n-type, doped with Si for example, though any suitable dopant may be used. Edge dislocations 29, 30, 31, and 32 begin in nucleation layer 16 and continue in high temperature layer 18. The inventors have observed that over 70% of the dislocations in high temperature layer 18 are edge dislocations, and less than 30% of the dislocations are mixed or screw dislocations. The total dislocation density in such layers may be substantially the same as or slightly higher than conventional devices, for example, between 10⁸ and 10⁹ cm⁻². When InN is included in nucleation layer 16 and/or high temperature layer 18, for example up to 5% InN, the percentage of edge dislocations increases. For example, in devices with InGaN high temperature layers 18, the inventors have observed that up to 95% of the dislocations are edge dislocations.

One or more layers that encourage the bending of edge dislocations 29-32 are grown over high temperature layer 18. Bending of edge dislocations has been observed at the interface between layers of different composition or doping concentration, or between layers grown at different growth temperatures. For example, in the device illustrated in FIG. 1, layer 20, the first layer grown over high temperature layer 18, may have a different growth temperature, InN composition and/or a silicon concentration than high temperature layer 18. The difference in growth temperature, composition and/or dopant concentration between layers 18 and 20 causes a difference in strain between these layers, which causes dislocations 29-32 to bend, as illustrated by dislocation 33 in layer 20.

At the interface between layers 20 and 22, the strain is again changed, encouraging further bending of the edge dislocations. An edge dislocation may bend to an orientation parallel to the major growth surface, as illustrated by dislocation 35. Two dislocations may bend to an orientation parallel to the major growth surface, then join, as illustrated by dislocation 34. Dislocation 36 is further bent within layer 22, though not to an orientation parallel to the major growth surface.

Optional additional layers 24 that encourage further bending of the edge dislocations may be grown over layer 22.

In some embodiments, the InN composition in dislocation bending layers 20, 22, and 24 increases as the layers get further from substrate 10. In some embodiments, as the InN composition increases, the thickness of the layers decreases. In one example, each of layers 20, 22, and 24 are InGaN, layer 20 has an InN composition up to 5% and a thickness up to 500 nm, layer 22 has an InN composition up to 10% and a thickness up to 300 nm, and layer 24 has an InN composition up to 20% and a thickness up to 50 nm.

In some embodiments, additional layers 24 include a superlattice structure of thin, alternating high and low InN composition layers. Each pair of layers may have a thickness between 1 nm and 1000 nm. The two layers in each pair may have the same or different thicknesses. The total thickness of the superlattice may be between several nanometers and several microns. The number of layer pairs included in the superlattice may be between 2 and 100 or more. In one example, the superlattice is composed of alternating InGaN layers of 3% InN and 6% InN, with each layer being 3 nm thick. In another example, the superlattice is composed of alternating layers of GaN and 6% InN InGaN, with each layer being 3 nm thick.

A GaN/InGaN or InGaN/InGaN superlattice may be included in a device to improve surface morphology. Growth of InGaN layers, for example an InGaN high temperature layer 18, can cause pits to form on the surface of the InGaN layer due to the relatively low growth temperature required to incorporate InN. By growing a superlattice, pit formation and poor surface morphology resulting from growth of the high InN layers in the superlattice may be mitigated by subsequent growth of the low InN layers in the superlattice.

The regions 38 grown above bent dislocations 34, 35, and 36 may be more relaxed than surrounding regions because a larger volume of the crystal has slipped or relaxed near the bent dislocations, than near straight dislocations. In general, the strain in a layer is an average of the strain states across the layer. Accordingly, for a given composition, a layer including relaxed regions 38 may be less strained than a layer without relaxed regions 38.

Device layers 26, as described above, are grown over the top dislocation bending layer.

Growth of device layers including one or more light emitting layers over edge-dislocation templates, such as the structures in some of the embodiments described above, may reduce the strain in the light emitting layer. For example, an InGaN layer that emits blue light may have the composition In_{0.12}Ga_{0.88}N, a composition with a relaxed lattice constant of 3.23 Å. The strain in the light emitting layer is determined by the difference between the in-plane lattice constant in the light emitting layer (often between 3.183 and 3.189 Å for a light emitting layer grown on a conventional GaN buffer layer) and the relaxed lattice constant of the light emitting layer, thus strain may be expressed as |(aᵢₙ₋ₚₗₐₙₑ−a_{relaxed})|/a_{relaxed}, as defined in Eq. (2). In the case of a conventional In_{0.12}Ga_{0.88}N layer, the strain is between |(3.189 Å-3.23 Å)|/3.23 Å and |(3.182 Å-3.23 Å)|/3.23 Å, between about 1.23% and 1.49%. If a light emitting layer of the same composition is grown on an edge-dislocation template such as the structures described above, the strain may be reduced or eliminated. In some embodiments of the invention, the strain in the light emitting layer of a device emitting light between 430 and 480 nm may be reduced to less than 1.4%, more preferably to less than 1%, and more preferably to less than 0.5%.

An InGaN layer that emits cyan light may have the composition In_{0.16}Ga_{0.84}N, a composition with a relaxed lattice constant of 3.24 Å, resulting in strain between about 1.6% and 1.8% when grown on a conventional GaN buffer layer. In some embodiments of the invention, the strain in the light emitting layer of a device emitting light between 480 and 520 nm may be reduced to less than 1.6%, more preferably to less than 1.5%, and more preferably to less than 1%.

An InGaN layer that emits green light may have the composition In_{0.2}Ga_{0.8}N, a composition with a relaxed lattice constant of 3.26 Å, resulting in strain between about 2.1% and 2.4% when grown on a conventional GaN buffer layer. In some embodiments of the invention, the strain in the light emitting layer of a device emitting light between 520 and 560 nm may be reduced to less than 2.4%, more preferably to less than 2%, and more preferably to less than 1.5%.

In a device including a GaN high temperature layer 18 and an InGaN light emitting layer configured to emit light with a peak wavelength of about 530 nm, the inventors observed an a-lattice constant in high temperature layer 18 of 3.189 Å and an a-lattice constant in the light emitting layer of 3.192 Å. The strain in the light emitting layer of this device is about 2.1%.

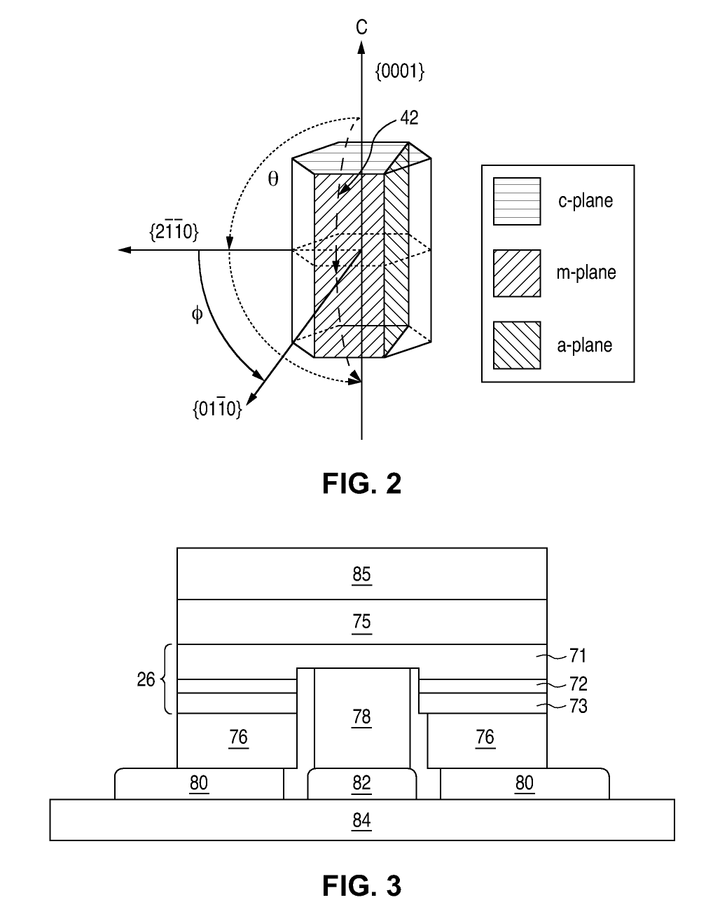

The growth templates described above and device layers may be grown on a surface of a sapphire or SiC growth substrate that is tilted from a major crystallographic plane of the sapphire, according to embodiments of the invention. FIG. 2 illustrates the c-plane, m-plane, and a-plane of sapphire. III-nitride devices are often grown over the c-plane, r-plane, m-plane, or a-plane of sapphire. In embodiments of the invention, a sapphire substrate may be sliced and polished such that the growth surface over which the III-nitride device layers are grown is tilted in a direction 42 from the c-plane, r-plane, m-plane, or a-plane, for example by more than 0.1°. A light emitting layer grown over such a substrate may experience reduced spinodal decomposition and reduced strain in the light emitting layers. Such a substrate may be used to grow any of the templates described above.

The semiconductor structures described above may be included in any suitable configuration of a light emitting device, such as a device with contacts formed on opposite sides of the device or a device with both contacts formed on the same side of the device. When both contacts are disposed on the same side, the device may be formed either with transparent contacts and mounted such that light is extracted either through the same side on which the contacts are formed, or with reflective contacts and mounted as a flip chip, where light is extracted from the side opposite the side on which the contacts are formed.

FIG. 3 illustrates a portion of one example of a suitable configuration, a flip chip device from which the growth substrate has been removed. As described above, the device layers 26 include a light emitting region 72 including at least one light emitting layer sandwiched between an n-type region 71 including at least one n-type layer and a p-type region 73 including at least one p-type layer. N-type region 71 may be a portion of the growth template, or a separate structure. A portion of p-type region 73 and light emitting region 72 is removed to form a mesa that exposes a portion of n-type region 71. Though one via exposing a portion of n-type region 71 is shown in FIG. 3, it is to be understood that multiple vias may be formed in a single device. N- and p-contacts 78 and 76 are formed on the exposed parts of n-type region 71 and p-type region 73, for example by evaporating or plating. Contacts 78 and 76 may be electrically isolated from each other by air or a dielectric layer. After contact metals 78 and 76 are formed, a wafer of devices may be diced into individual devices, then each device is flipped relative to the growth direction and mounted on a mount 84, in which case mount 84 may have a lateral extent larger than that of the device, as illustrated in FIG. 3. Alternatively, a wafer of devices may be connected to a wafer of mounts, then diced into individual devices. Mount 84 may be, for example, semiconductor such as Si, metal, or ceramic such as AlN, and may have at least one metal pad 80 which electrically connects to p-contacts 76 and at least one metal pad 82 which electrically connects to the n-contacts 78. Interconnects (not shown in FIG. 3) disposed between contacts 76 and 78 and pads 80 and 82 connect the semiconductor device to mount 84. The interconnects may be, for example, elemental metals such as gold, or solder.

After mounting, the growth substrate (not shown) is removed by a process suitable to the substrate material, such as etching or laser melting. A rigid underfill may be provided between the device and mount 84 before or after mounting to support the semiconductor layers and prevent cracking during substrate removal. Template 75, on which device layers 26 are grown, may be left intact, completely removed, or partially removed, for example by etching. The surface exposed by removing the growth substrate and any semiconductor material may be roughened, for example by an etching process such as photoelectrochemical etching or by a mechanical process such as grinding. Roughening the surface from which light is extracted may improve light extraction from the device. Alternatively, a photonic crystal structure may be formed in the surface. A structure 85 such as a phosphor layer or secondary optics known in the art such as dichroics or polarizers may be applied to the emitting surface.

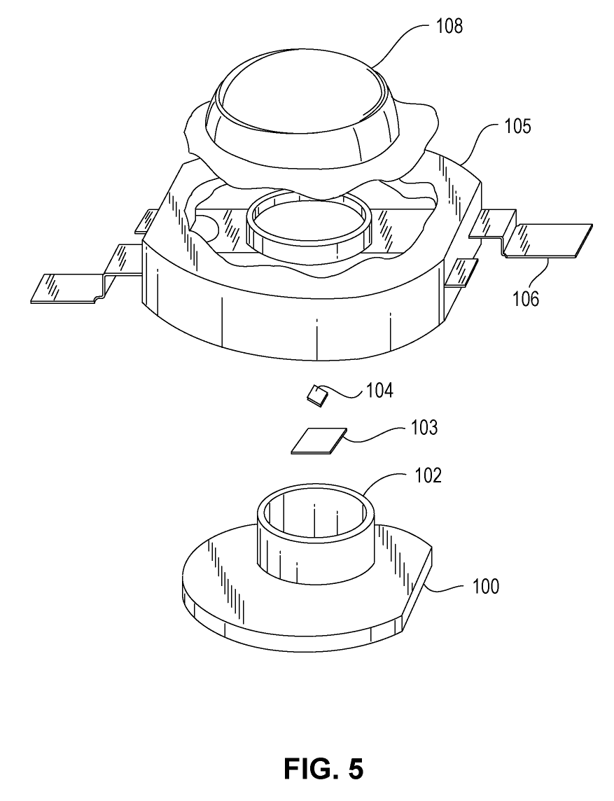

FIG. 5 is an exploded view of a packaged light emitting device, as described in more detail in U.S. Pat. No. 6,274,924. A heat-sinking slug 100 is placed into an insert-molded leadframe. The insert-molded leadframe is, for example, a filled plastic material 105 molded around a metal frame 106 that provides an electrical path. Slug 100 may include an optional reflector cup 102. The light emitting device die 104, which may be any of the devices described in the embodiments above, is mounted directly or indirectly via a thermally conducting submount 103 to slug 100. A cover 10⁸, which may be an optical lens, may be added.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A device comprising:
a wurtzite III-nitride semiconductor structure comprising:
a light emitting layer disposed between an n-type region and a p-type region;
a template layer grown before the light emitting layer, wherein:
the template layer has a total number of dislocations; and
at least 70% of the dislocations are edge dislocations.

2. The device of claim 1 further comprising an interface parallel to a major surface of the light emitting layer and disposed between the template layer and the light emitting layer, wherein:
a majority of the edge dislocations in the template layer intersect a major surface of the template layer at an angle substantially equal to 90 degrees; and
at least a portion of the edge dislocations in the template layer propagate to the interface; and
at least a portion of the edge dislocations propagated to the interface intersect the interface at an angle less than 90 degrees.

3. The device of claim 1 wherein the semiconductor structure further comprises a dislocation bending layer disposed between the template layer and the light emitting layer, wherein at least a portion of the edge dislocations in the template layer are propagated into the dislocation bending layer and wherein at least a portion of the edge dislocations in the dislocation bending layer have a different orientation than the corresponding edge dislocations in the template layer.

4. The device of claim 3 wherein a magnitude of strain in the dislocation bending layer is different from a magnitude of strain in the template layer.

5. The device of claim 3 wherein the dislocation bending layer has an InN composition greater than an InN composition in the template layer.

6. The device of claim 3 wherein the dislocation bending layer is thinner than the template layer.

7. The device of claim 3 wherein the dislocation bending layer has a higher concentration of n-type dopant than the template layer.

8. The device of claim 3 further comprising:
a first interface disposed between the template layer and the dislocation bending layer; and
a second interface disposed between the light emitting layer and the dislocation bending layer;
wherein:
a majority of the edge dislocations in the template layer intersect the first interface at an angle substantially equal to 90 degrees; and
at least a portion of the edge dislocations propagated into the dislocation bending layer intersect the second interface at an angle less than 90 degrees.

9. The device of claim 1 wherein the template layer comprises a plurality of non-single-crystal nucleation layers.

10. The device of claim 1 further comprising first and second contacts electrically connected to the n-type region and the p-type region, wherein the first and second contacts are both formed on a same side of the semiconductor structure.

11. A method comprising:
growing a III-nitride structure on a substrate, the III-nitride structure comprising:
a template layer, wherein:
the template layer has a total number of dislocations; and
at least 70% of the dislocations are edge dislocations;
a dislocation bending layer, wherein:
the dislocation bending layer is grown over the template layer;
at least a portion of the edge dislocations in the template layer are propagated into the dislocation bending layer; and
at least a portion of the edge dislocations in the dislocation bending layer have a different orientation than the corresponding edge dislocations in the template layer;
a III-nitride light emitting layer grown over the dislocation bending layer, wherein the III-nitride light emitting layer is disposed between an n-type region and a p-type region.

12. The method of claim 11 wherein growing a III-nitride structure further comprises:
growing a first nucleation layer directly on the substrate; and
growing a second nucleation layer over the first nucleation layer, wherein the second nucleation layer is thinner than the first nucleation layer and grown more slowly than the first nucleation layer.

13. The method of claim 11 further comprising:
connecting the III-nitride structure to a host; and
removing the substrate.
